(19) United States
(12) Patent Application Publication
(10) Pub. No.: US 2024/0194748 A1
(43) Pub. Date: Jun. 13, 2024

(54) DRIVING BACKPLANE AND DISPLAY PANEL

(71) Applicant: SHENZHEN CHINA STAR OPTOELECTRONICS SEMICONDUCTOR DISPLAY TECHNOLOGY CO., LTD., SHENZHEN (CN)

(72) Inventor: Chuanbao Luo, Shenzhen (CN)

(73) Assignee: SHENZHEN CHINA STAR OPTOELECTRONICS SEMICONDUCTOR DISPLAY TECHNOLOGY CO., LTD., SHENZHEN (CN)

(21) Appl. No.: 18/148,745

(22) Filed: Dec. 30, 2022

(30) Foreign Application Priority Data
Dec. 13, 2022 (CN) 202211601826.4

(51) Int. Cl. H01L 29/417; H01L 29/786; H01L 33/38; H01L 33/62

(52) U.S. Cl. CPC H01L 29/41733; H01L 29/78633; H01L 29/78696; H01L 33/382; H01L 33/62

(57) ABSTRACT

The present application provides a driving backplane and a display panel. The driving backplane includes a substrate, a first conductive layer, an active layer, an insulating layer, and a second conductive layer. A source contact portion covers part of a sub-source electrode, a drain contact portion covers part of a sub-drain electrode, and a channel portion covers a gap between the sub-source electrode and the sub-drain electrode. The second conductive layer is disposed on a side of the insulating layer away from the substrate. The second conductive layer includes a main drain electrode and a gate electrode, the main drain is connected to the sub-drain electrode, and an orthographic projection of the gate electrode on the substrate at least covers an orthographic projection of the channel portion on the substrate.

### FIELD OF INVENTION

The present application relates to a field of display technology, in particular, to a driving backplane and a display panel.

### DESCRIPTION OF PRIOR ART

As the continuous development of displays and panels, micro/mini light-emitting diode (MLED) displays have gradually used in the public. Compared with organic light-emitting diode (OLED) displays, MLED displays have better performance in contrast and brightness, lower cost, and are beautiful in appearance.

In the MLED display technology, top-gate thin-film transistors are widely used due to their large capacitance in a unit occupied area. However, manufacturing such top-gate thin-film transistors requires more photomasks. In this regard, a thin-film transistor with gate/source/drain one layer (GSD, a gate electrode, a main source electrode, and a main drain electrode are located on a same layer) saves a mask and reduces the cost compared with conventional top-gate thin-film transistor. However, it is difficult for the GSD thin-film transistor to achieve narrow channel and high mobility.

### SUMMARY

The present application provides a driving backplane and a display panel, which can realize narrow channel and improve mobility of a channel portion.

The present application provides a driving backplane, including:
a substrate;
a first conductive layer, disposed on the substrate, comprising a sub-source electrode and a sub-drain electrode;
an active layer, disposed on a side of the first conductive layer away from the substrate, comprising a source contact portion, a drain contact portion, and a channel portion connected to the source contact portion and the drain contact portion, wherein the source contact portion covers part of the sub-source electrode, the drain contact portion covers part of the sub-drain electrode, and the channel portion covers a gap between the sub-source electrode and the sub-drain electrode;
an insulating layer, disposed on a side of the first conductive layer away from the substrate, covering the first conductive layer and the active layer; and
a second conductive layer, disposed on a side of the insulating layer away from the substrate, comprising a gate electrode and a main drain electrode connected to the sub-drain electrode, wherein an orthographic projection of the gate electrode on the substrate at least overlaps an orthographic projection of the channel portion on the substrate.

Optionally, in some embodiments of the present application, a material of the first conductive layer is different from a material of the second conductive layer, and a linewidth of the first conductive layer is less than a linewidth of the second conductive layer.

Optionally, in some embodiments of the present application, the orthographic projection of the gate electrode on the substrate overlaps at least part of an orthographic projection of the sub-source electrode on the substrate, and the orthographic projection of the gate electrode on the substrate overlaps at least part of an orthographic projection of the sub-drain electrode on the substrate.

Optionally, in some embodiments of the present application, the orthographic projection of the gate electrode on the substrate overlaps the orthographic projection of the channel portion on the substrate; the source contact portion comprises a first doped region, and the drain contact portion comprises a second doped region.

Optionally, in some embodiments of the present application, the driving backplane further includes a third conductive layer, the third conductive layer is located on a side of the second conductive layer away from the substrate, the third conductive layer includes a connecting electrode, the connecting electrode is connected to the sub-source electrode, and an orthographic projection of the connecting electrode on the substrate overlapping an orthographic projection of the active layer on the substrate.

Optionally, in some embodiments of the present application, the second conductive layer further comprises a main source electrode connected to the sub-source electrode and the connecting electrode, and wherein the gate electrode is located between the main source electrode and the main drain electrode.

Optionally, in some embodiments of the present application, the orthographic projection of the connecting electrode on the substrate completely overlaps the orthographic projection of the active layer on the substrate, and overlaps at least part of an orthographic projection of the main drain electrode on the substrate; in a direction perpendicular to the substrate, a length of an overlapping part of the connecting electrode and the main drain electrode ranges from 2 microns to 5 microns.

Optionally, in some embodiments of the present application, the driving backplane further includes a third conductive layer, the third conductive layer is located on a side of the second conductive layer away from the substrate, and the third conductive layer includes a protective electrode and a connecting electrode connected to the sub-source electrode,
wherein an orthographic projection of the protective electrode on the substrate at least overlaps an orthographic projection of the active layer on the substrate.

Optionally, in some embodiments of the present application, the third conductive layer comprises a conductive metal layer and an anti-reflection layer disposed on a side of the conductive metal layer away from the substrate.

Optionally, in some embodiments of the present application, the driving backplane further includes a light-shielding layer, the light-shielding layer is disposed on a side of the first conductive layer near the substrate, the light-shielding layer includes a light-shielding element, and an orthographic projection of the light-shielding element on the substrate overlaps an orthographic projection of the active layer on the substrate; and
the insulating layer is provided with a third through hole, the third through hole penetrating through the insulating layer and extends to the light-shielding element, a side surface of the light-shielding element away from the substrate is exposed from the third through hole, and the light-shielding element is connected to the main drain through the third through hole.

Optionally, in some embodiments of the present application, the driving backplane further includes a light-shielding layer and a buffer layer, the light-shielding layer is disposed on a side of the first conductive layer near the substrate, and the buffer layer is disposed between the first conductive layer and the light-shielding layer;
the light-shielding layer includes a light-shielding element, and an orthographic projection of the light-shielding element on the substrate overlaps an orthographic projection of the active layer on the substrate, the buffer layer is provided with a contact hole extending to the light-shielding element, a side surface of the light-shielding element away from the substrate is exposed from the contact hole, and the light-shielding element is connected to the sub-drain through the contact hole.

Optionally, in some embodiments of the present application, a thickness of the active layer ranges from 300 angstroms to 500 angstroms, and a length of the channel portion ranges from 3 microns to 5 microns.

Accordingly, the present application also provides a display panel, the display panel includes a driving backplane and light-emitting units disposed on the driving backplane, and the driving backplane is defined as above.

The present application discloses a driving backplane and a display panel. The driving backplane includes a substrate, a first conductive layer, an active layer, an insulating layer, and a second conductive layer. The first conductive layer is disposed on the substrate. The active layer includes a source contact portion, a drain contact portion, and a channel portion connected to the source contact portion and the drain contact portion. The source contact portion covers part of the sub-source electrode, the drain contact portion covers part of the sub-drain electrode, and the channel portion covers a gap between the sub-source electrode and the sub-drain electrode. The insulating layer is disposed on a side of the first conductive layer away from the substrate, and covers the first conductive layer and the active layer. The second conductive layer is disposed on a side of the insulating layer away from substrate. The second conductive layer includes a main drain electrode and a gate electrode, the main drain electrode is connected to the sub-drain electrode, and an orthographic projection of the gate electrode on the substrate at least covers an orthographic projection of the channel portion on the substrate. In the present application, because the channel portion is located between the sub-source electrode and the sub-drain electrode, a length of the channel portion can be adjusted by controlling a distance between the sub-source electrode and the sub-drain electrode, so as to narrow the channel portion, improve the mobility of the channel portion, and improve the reliability of the driving backplane.

### BRIEF DESCRIPTION OF DRAWINGS

In order to explain the technical solutions in the embodiments of the present application more clearly, the following will briefly introduce the drawings needed in the description of the embodiments. Obviously, the drawings in the following description are only some embodiments of the present application. For those skilled in the art, other drawings can be obtained based on these drawings without creative work.

FIG. 1 is a first schematic structural diagram of a driving backplane provided by the present application;

FIG. 2 is a second schematic structural diagram of the driving backplane provided by the present application;

FIG. 3 is a third schematic structural diagram of the driving backplane provided by the present application;

FIG. 4 is a fourth schematic structural diagram of the driving backplane provided by the present application;

FIG. 5 is a fifth schematic structural diagram of the driving backplane provided by the present application;

FIG. 6A-FIG. 6F are schematic structural diagrams obtained in each step of a manufacturing method of the driving backplane provided by the present application;

FIG. 7 is a schematic structural diagram of a display panel provided by the present application.

### DETAILED DESCRIPTION OF EMBODIMENTS

In the following, the technical scheme in the embodiment of the present application will be described clearly and completely in combination with the drawings. Obviously, the described embodiments are only a part of the embodiments of the present application, rather than all the embodiments. Based on the embodiments of the present application, all other embodiments obtained by those skilled in the art without creative work fall within the protection scope of the present application.

In the description of present application, terms “first” and “second” are only used for descriptive purposes and can not be understood as indicating or implying relative importance or implicitly indicating the number of indicated technical features. Thus, the features defining “first” and “second” may explicitly or implicitly include one or more of the features. Therefore, it cannot be understood as a limitation on the present application. In addition, it is to be noted that, unless otherwise specified and defined, terms “connected” and “fixed” should be understood in a broad sense, for example, it may be a fixed connection, a detachable connection, or a whole; it may be a mechanical connection or an electrical connection; it may be a directly connection or an indirectly connection through an intermediate media; and it may be an internal connection of two components or an interaction relationship between two components. For those skilled in the art, meanings of the above terms in the present disclosure can be understood according to situations.

The present application provides a driving backplane and a display panel, which will be described in detail below. It should be noted that the order of description of the following embodiments is not a limitation on the preferred order of the embodiments of the present application.

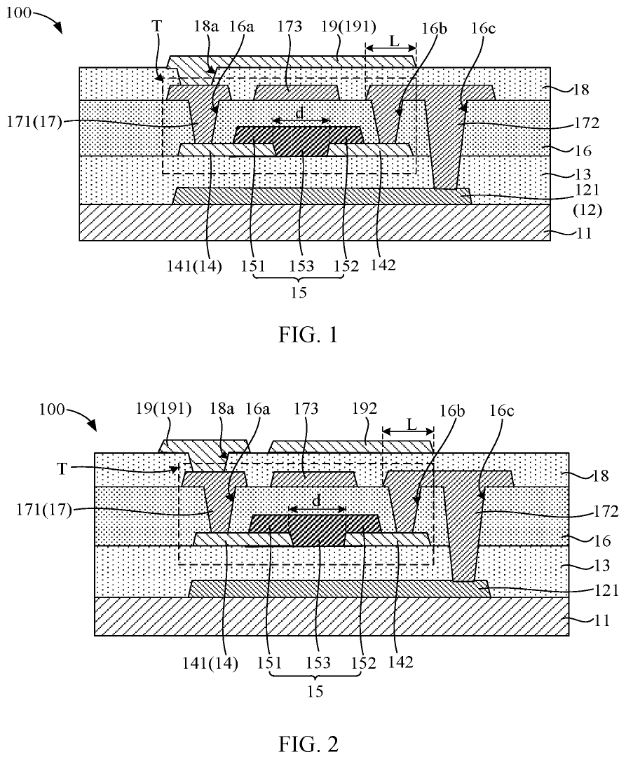

Referring to FIG. 1, FIG. 1 is a first schematic structural diagram of a driving backplane provided by the present application. In the embodiments of the present application, the driving backplane 100 includes a substrate 11, a first conductive layer 14, an active layer 15, an insulating layer 16, and a second conductive layer 17.

The first conductive layer 14 is disposed on the substrate 11. The first conductive layer 14 includes a sub-source electrode 141 and a sub-drain electrode 142. The active layer 15 is disposed on a side of the first conductive layer 14 away from the substrate 11. The active layer 15 includes a source contact portion 151, a drain contact portion 152, and a channel portion 153 connected to the source contact portion 151 and the drain contact portion 152. The source contact portion 151 covers part of the sub-source electrode 141. The drain contact portion 152 covers part of the sub-drain electrode 142. The channel portion 153 covers a gap between the sub-source electrode 141 and the sub-drain electrode 142. The insulating layer 16 is disposed on a side of the first conductive layer 14 away from the substrate 11, and covers the first conductive layer 14 and the active layer 15. The second conductive layer 17 is disposed on a side of the insulating layer 16 away from the substrate 11. The second conductive layer 17 includes a main drain electrode 172 and a gate electrode 173. The main drain electrode 172 is connected to the sub-drain electrode 142. An orthographic projection of the gate electrode 173 on the substrate 11 at least covers an orthographic projection of the channel portion 153 on the substrate 11.

The active layer 15, the sub-source electrode 141, the sub-drain electrode 142, the main source electrode 171, the main drain electrode 172, and the gate electrode 173 form a thin-film transistor. The thin-film transistor is a top-gate thin-film transistor. The sub-source electrode 141 serves as a source electrode of the thin-film transistor. The main drain electrode 172 and the sub-drain electrode 142 are connected to form a drain electrode of the thin-film transistor.

The embodiments of the present application dispose the main source electrode 171, the main drain electrode 172, and the gate electrode 173 on a same layer. This can use a same photomask to pattern the conductive layer of the same layer, save the quantity of photomasks, and reduce production costs. However, etching is easy to cause excessive CD loss of the conductive layer, and excessive CD loss causes that a linewidth of the conductive layer must be set too large, which makes it difficult to achieve narrow channel by controlling a linewidth of the gate electrode 173.

In this regard, the embodiments of the present application dispose the sub-source electrode 141 and the sub-drain electrode 142, and dispose the active layer 15 to cover part of the sub-source electrode 141, part of the sub-drain electrode 142, and the gap between the sub-source electrode 141 and the sub-drain electrode 142, so that the channel portion 153 is located between the sub-source electrode 141 and the sub-drain electrode 142. Then, a length d of the channel portion 153 can be adjusted by controlling a distance between the sub-source electrode 141 and the sub-drain electrode 142. This makes it easier to narrow the channel than correlating through plasma and other conductive methods. Since mobility increases as the length d of the channel portion 153 decreases, mobility of the thin-film transistor can be increased.

In addition, since the active layer 15 is disposed on the side of the first conductive layer 14 away from the substrate 11, when the first conductive layer 14 is etched to form the sub-source electrode 141 and the sub-drain electrode 142, the etching effect of an etching solution on the active layer 15 can be avoided, thereby improving the stability of the driving backplane 100.

In the embodiments of the present application, a material of the active layer 15 can be single crystal silicon, low temperature polysilicon, or oxide semiconductor material. The oxide semiconductor materials can be indium gallium zinc oxide (IGZO), indium gallium zinc tin oxide (IGZTO), IZO, gallium indium oxide (IGO), indium gallium tin oxide (IGTO), indium zinc tin oxide material (IZTO), ITO, zinc aluminum tin oxide (ATZO), zinc aluminum indium oxide (AIZO), etc.

In the embodiments of the present application, a thickness of the active layer 15 ranges from 300 angstroms to 500 angstroms. A length d of the channel portion 153 ranges from 3 micrometers to 5 micrometers. A thickness of the active layer 15 may refer to a thickness of the channel portion 153 along a direction perpendicular to the substrate 11.

For example, the thickness of the active layer 15 may be 300 angstroms, 350 angstroms, 400 angstroms, 450 angstroms, 500 angstroms, and so on. The length d of the channel portion 153 may be 3 microns, 3.5 microns, 4 microns, 4.5 microns, 5 microns, or the like.

The active layer 15 of the embodiments of the present application is thinner, thereby reducing a resistance value of the active layer 15, and improving the performance of the thin-film transistor. In the embodiments of the present application, the length d of the channel portion 153 is small, the channel is narrowed, and the mobility of the thin-film transistor is improved.

In the embodiments of the present application, a material of the first conductive layer 14 can be molybdenum (Mo), Mo/aluminum (Al), Mo/copper (Cu), MoTi (titanium)/Cu, MoTi/Cu/MoTi, Ti/Al/Ti, Ti/Cu/Ti, Mo/Cu/indium zinc oxide (IZO), IZO/Cu/IZO, Mo/Cu/ITO (indium tin oxide), etc., the present application does not make specific defined.

In the embodiments of the present application, a material of the second conductive layer 17 may be Mo, Mo/Al, Mo/Cu, MoTi/Cu, MoTi/Cu/MoTi, Ti/Al/Ti, Ti/Cu/Ti, Mo/Cu/IZO, IZO/Cu/IZO, Mo/Cu/ITO, etc., the present application does not make specific defined.

In detail, in some embodiments of the present application, the material of the first conductive layer 14 and the material of the second conductive layer 17 are different. A linewidth of the first conductive layer 14 is less than a linewidth of the second conductive layer 17.

The material of the first conductive layer 14 is mainly metal oxides with small changes in key dimension and low resistance value, such as ITO, IZO, ANCL, and other metals or metal oxides with low resistance value. ANCL refers to a mixture of Al, nickel (Ni), Cu, lanthanum (La), and performance of ANCL is stable.

The etching key dimension of the first conductive layer 14 changes little, the sub-source electrode 141 with a smaller linewidth and the sub-drain electrode 142 with a smaller linewidth can be obtained through etching. Therefore, the distance between the sub-source electrode 141 and the sub-drain electrode 142 is more controllable, and it is easier to narrow channel. At a same time, the uniformity of the linewidth of the sub-source electrode 141 and the linewidth of the sub-drain electrode 142 can be realized, and stable electrical characteristics of the transistor can be realized.

Further, a resistance value of the first conductive layer 14 is greater than a resistance value of the second conductive layer 17. For example, the second conductive layer 17 may be a single layer of metal copper, a bottom layer of molybdenum and an upper layer of copper, a bottom layer of molybdenum titanium alloy and an upper layer of copper, and other structures. It is understandable that metals with small deviations in linewidth generally have poor electrical conductivity. Therefore, the embodiments of the present application sets the resistance value of the second conductive layer 17 to be lower than the resistance value of the first conductive layer 14, which can reduce the impedance of the main source electrode 171 and the main drain electrode 172. Due to the main source electrode 171 is connected to the sub-source electrode 141, and the main drain electrode 172 is connected to the sub-drain electrode 142, the resistance values of the source electrode and the drain electrode can be reduced, the performance of the thin-film transistor can be improved, and the load of the driving backplane 100 can be reduced.

In the embodiments of the present application, a material of the insulating layer 16 may be selected from silicon oxide (SiOx), silicon nitride (SiNx), aluminum trioxide (Al₂O₃), and stacked layers thereof. For example, the material of the insulating layer 16 may be Al₂O₃/SiNx/SiOx laminated layer or SiOx/SiNx/SiOx laminated layer, and the present application does not make specific defined for this.

The insulating layer 16 is provided with a first through hole 16a and a second through hole 16b. The first through hole 16a extends to the sub-source electrode 141, and a side surface of the sub-source electrode 141 away from the substrate 11 is exposed from the first through hole 16a. The second through hole 16b extends to the sub-drain electrode 142, and a side surface of the sub-drain electrode 142 away from the substrate 11 is exposed from the second through hole 16b. The main source electrode 171 is connected to the sub-source electrode 141 through the first through hole 16a. The main drain electrode 172 is connected to the sub-drain electrode 142 through the second through hole 16b.

In the embodiments of the present application, the orthographic projection of the gate electrode 173 on the substrate 11 overlaps at least part of an orthographic projection of the sub-source electrode 141 on the substrate 11. The orthographic projection of the gate electrode 173 on the substrate 11 overlaps at least part of an orthographic projection of the sub-drain electrode 142 on the substrate 11.

It can be understood that, since the source contact portion 151 covers part of the sub-source electrode 141, the drain contact portion 152 covers part of the sub-drain electrode 142, thus, in the direction perpendicular to the substrate 11, the gate electrode 173, the source contact portion 151, and the sub-source electrode 141 partially overlap, and the gate electrode 173, the drain contact portion 152, and the sub-drain 142 electrode partially overlap. Therefore, the source contact portion 151 can be controlled by the electric field between the gate electrode 173 and the sub-source electrode 141 on the upper and lower sides thereof without conducting. Similarly, the drain contact portion 152 can be controlled by the electric field between the gate electrode 173 and the sub-source electrode 141 on the upper and lower sides thereof without conducting. Therefore, in the process of making the driving backplane 100, the steps of conducting the source contact portion 151 and the drain contact portion 152 can be omitted, and the process can be simplified.

In detail, the orthographic projection of the gate electrode 173 on the substrate 11 may overlap an orthographic projection of the active layer 15 on the substrate 11. Thus, the orthographic projection of the gate electrode 173 on the substrate 11 and the orthographic projection of the sub-source electrode 141 on the substrate 11 are completely overlap. The orthographic projection of the gate electrode 173 on the substrate 11 and the orthographic projection of the sub-drain electrode 142 on the substrate 11 are completely overlap. The contact yield between the sub-source electrode 141 and the active layer 15, and the contact yield between the sub-drain electrode 142 and the active layer 15 are further improved.

In the embodiments of the present application, the second conductive layer 17 may further include a main source electrode 171. The gate electrode 173 is located between the main source electrode 171 and the main drain electrode 172. The main source electrode 171 is connected to the sub-source electrode 141.

The active layer 15, the sub-source electrode 141, the sub-drain electrode 142, the main source electrode 171, the main drain electrode 172, and the gate electrode 173 form a thin-film transistor. The thin-film transistor is a top-gate thin-film transistor. The main source electrode 171 is connected to the sub-source electrode 141 to constitute a source electrode of the thin-film transistor. The main drain electrode 172 is connected to the sub-drain electrode 142 to constitute a drain electrode of the thin-film transistor.

In the embodiments of the present application, the driving backplane 100 also includes a passivation layer 18 and a third conductive layer 19. The passivation layer 18 is located on a side of the second conductive layer 17 away from the substrate 11. The third conductive layer 19 is located on a side of the passivation layer 18 away from the substrate 11.

A material of the passivation layer 18 may be SiOx, SiNx, SiNx/SiOx, SiNOx, and the like. A material of the third conductive layer 19 may be ITO, IZO, ITO/Ag/ITO, IZO/Ag/IZO, Mo/Cu, MoTi/Cu/MoTi, and the like.

The third conductive layer 19 includes a connecting electrode 191. The passivation layer 18 is provided with a connecting hole 18a. A side surface of the main source electrode 171 away from the substrate 11 is exposed from the connecting hole 18a. The connecting electrode 191 is connected to the main source electrode 171 through the connecting hole 18a. An orthographic projection of the connecting electrode 191 on the substrate 11 at least covers the orthographic projection of the active layer 15 on the substrate 11.

It can be understood that the main source electrode 171, the main drain electrode 172, and the gate electrode 173 are disposed in a same layer, which reduces a quantity of non-metallic film layers separating each conductive layer while saving the quantity of photomasks. The water and oxygen isolation ability is weaker than that of the top-gate structure relatively including interlayer dielectric layer and passivation layer. At a same time, if the driving backplane 100 is applied to the micro-LED backlight panel, and there is no pixel defining layer and planarization layer in OLED, water and oxygen will have a greater impact on the driving backplane 100.

In this regard, the embodiments of the present application set that the orthographic projection of the connecting electrode 191 on the substrate 11 at least covers the orthographic projection of the active layer 15 on the substrate 11. That is, the connecting electrode 191 extends from a position corresponding to the main source electrode 171 to a position corresponding to the main drain electrode 172, and at least covers the upper part of the channel portion 153 of the active layer 15, so as to prevent water vapor in the environment from diffusing to the channel portion 153, and improve the reliability of the driving backplane 100.

Further, the orthographic projection of the connecting electrode 191 on the substrate 11 completely covers the orthographic projection of the active layer 15 on the substrate 11, and covers at least part of the orthographic projection of the main drain electrode 172 on the substrate 11. Along the direction perpendicular to the substrate 11, a length L of an overlapping part of the connecting electrode 191 and the main drain electrode 172 ranges from 2 micrometers to 5 micrometers. In this way, a shielding area of the active layer 15 is further increased to prevent water and oxygen erosion.

In detail, the length L of the overlap part of the connecting electrode 191 and the main drain electrode 172 may be 2 microns, 3 microns, 4 microns, 5 microns, etc.

In some embodiments of the present application, the third conductive layer 19 includes an anti-reflection layer and a conductive metal layer that are stacked. The anti-reflection layer is disposed on a side of the conductive metal layer away from the substrate 11.

A material of the anti-reflection layer may be indium zinc oxide, molybdenum oxide, or molybdenum nitride. A material of the conductive metal layer may be a composite metal layer formed of copper and molybdenum.

For example, the material of the anti-reflection layer is indium zinc oxide, and the material of the conductive metal layer is a composite metal layer formed of copper and molybdenum. Indium zinc oxide is used as a low reflection functional layer. Copper serves as the electrode layer. By disposing molybdenum between indium zinc oxide and copper, the adhesion between indium zinc oxide and copper can be improved.

The embodiments of the present application uses zinc oxide, molybdenum oxide, or molybdenum nitride to coat the conductive metal layer. Because zinc oxide, molybdenum oxide, or molybdenum nitride has good light absorption characteristics, which can reduce the light emitted by light-emitting units or the external loop ambient light entering the channel portion 153, to further improve the stability of the driving backplane 100.

In the embodiments of the present application, the driving backplane 100 also includes a light-shielding layer 12 and a buffer layer 13. The light-shielding layer 12 is disposed on a side of the first conductive layer 14 near the substrate 11. The buffer layer 13 is disposed between the first conductive layer 14 and the light-shielding layer 12.

Among them, a material of the light-shielding layer 12 may be a metal with excellent conductivity and good light-shielding properties. For example, the material of the light-shielding layer 12 is Mo, Mo/Al, Mo/Cu, MoTi/Cu, MoTi/Cu/MoTi, Ti/Al/Ti, Ti/Cu/Ti, Mo/Cu/IZO, IZO/Cu/IZO, Mo/Cu/ITO etc. A material of the buffer layer 13 may be SiOx, SiOx or SiNx/SiOx laminated layer, which plays a role of insulation protection.

The light-shielding layer 12 includes a light-shielding element 121. An orthographic projection of the light-shielding element 121 on the substrate 11 covers the orthographic projection of the active layer 15 on the substrate 11.

It can be understood that, after the active layer 15 is irradiated by the light from the side of the substrate 11, photogenerated carriers will increase, resulting in the thin-film transistor producing threshold voltage drifting, leakage current increase, and other undesirable phenomena. The light-shielding element 121 can block the light emitted from a direction of the substrate 11 away from the light-shielding element 121, thereby reducing the interference of external light on the active layer 15, and improving the operating performance of the driving backplane 100.

The insulating layer 16 is also provided with a third through hole 16c. The third through hole 16c penetrates through the insulating layer 16, and extends to the light-shielding element 121. A side surface of the light-shielding element 121 away from the substrate 11 is exposed from the third through hole 16c. The light-shielding element 121 is connected to the main drain electrode 172 through the third through hole 16c. Since the main drain electrode 172 is connected to the sub-drain electrode 142, the connection between the light-shielding element 121 and the sub-drain electrode 142 is realized.

By connecting the light-shielding element 121 and the main drain electrode 172 to form an equipotential, the voltage change on the light-shielding element 121 can be prevented from affecting the electrical properties of the active layer 15. The light-shielding element 121, the main drain electrode 172, and the sub-drain electrode 142 connected together further reduce the load of the driving backplane 100.

Referring to FIG. 2, FIG. 2 is a second schematic structural diagram of the driving backplane provided by the present application. A difference from the driving backplane 100 shown in FIG. 1 is that, in the embodiments of the present application, the third conductive layer 19 includes a connecting electrode 191 and a protective electrode 192. Among them, the connecting electrode 191 is connected to the main source electrode 171 through the connecting hole 18a. An orthographic projection of the protective electrode 192 on the substrate 11 at least covers the orthographic projection of the active layer 15 on the substrate 11.

In detail, the orthographic projection of the protective electrode 192 on the substrate 11 completely covers the orthographic projection of the active layer 15 on the substrate 11, and covers at least part of the orthographic projection of the main drain electrode 172 on the substrate 11. Along the direction perpendicular to the substrate 11, the length L of an overlap part of the protective electrode 192 and the main drain electrode 172 ranges from 2 micrometers to 5 micrometers. In this way, the shielding area of the active layer 15 is further increased to prevent water and oxygen erosion.

In detail, the length L of the overlap portion of the protective electrode 192 and the main drain electrode 172 may be 2 microns, 3 microns, 4 microns, 5 microns, etc.

The embodiments of the present application dispose the connecting electrode 191 and the protective electrode 192 separately, which can prevent the protective electrode 192 from affecting the function of the connecting electrode 191.

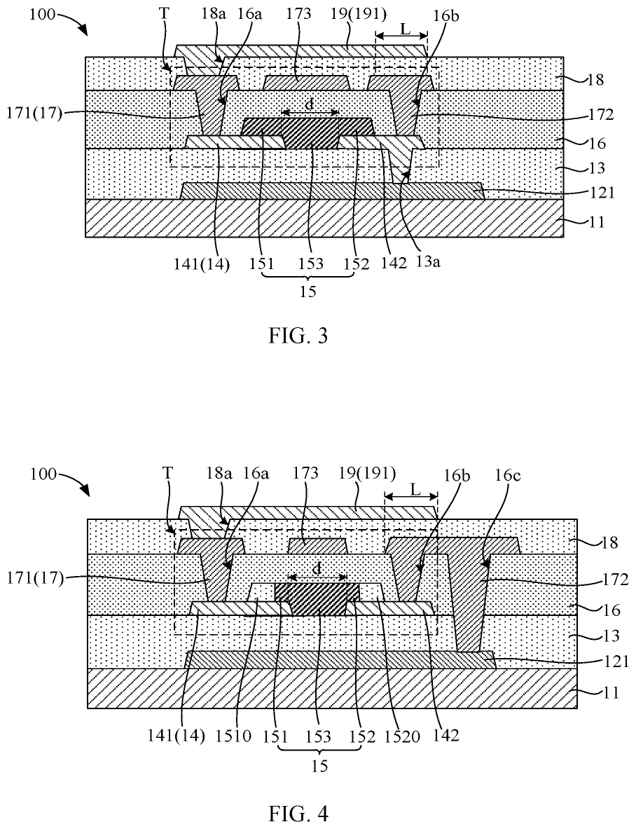

Referring to FIG. 3, FIG. 3 is a third schematic structural diagram of the driving backplane provided by the present application. A difference from the driving backplane 100 shown in FIG. 1 is that, in the embodiments of the present application, the buffer layer 13 is provided with a contact hole 13a. The contact hole 13a extends to the light-shielding element 121. A side surface of the light-shielding element 121 away from the substrate 11 is exposed from the contact hole 13a. The light-shielding element 121 is connected to the sub-drain electrode 142 through the contact hole 13a. Since the main drain electrode 172 is connected to the sub-drain electrode 142, the connection between the light-shielding element 121 and the main drain electrode 172 is realized.

The embodiments of the present application realize the connection of the light-shielding element 121, the sub-drain electrode 142, and the main drain electrode 172 by setting the contact hole 13a in the buffer layer 13, reduce a quantity of holes in the insulation layer 16, and thus improve the water resistance and oxygen isolation ability of the insulation layer 16.

Referring to FIG. 4, FIG. 4 is a fourth schematic structural diagram of the driving backplane provided by the present application. A difference from the driving backplane 100 shown in FIG. 1 is that, in the embodiments of the present application, the orthographic projection of the gate electrode 173 on the substrate 11 overlaps the orthographic projection of the channel portion 153 on the substrate 11. The source contact portion 151 includes a first doped region 1510. The drain contact portion 152 includes a second doped region 1520.

It can be understood that when the gate electrode 173 is only provided corresponding to the channel portion 153, the source contact portion 151 cannot be conducted under the electric field between the gate electrode 173 and the sub-source electrode 141. Similarly, the drain contact portion 152 cannot be conducted under the electric field between the gate electrode 173 and the sub-source electrode 141. In order to improve the connection yield between the sub-source electrode 141 and the source contact portion 151, and the connection yield between the sub-drain electrode 142 and the drain contact portion 152, the source contact portion 151 and the drain contact portion 152 need to be ion doped to form the first doped region 1510 and the second doped region 1520.

The first doped region 1510 is a part of the source contact portion 151, and the second doped region 1520 is a part of the drain contact portion 152, so as to prevent the channel portion 153 from being affected by the diffusion of doped ions under conductorization.

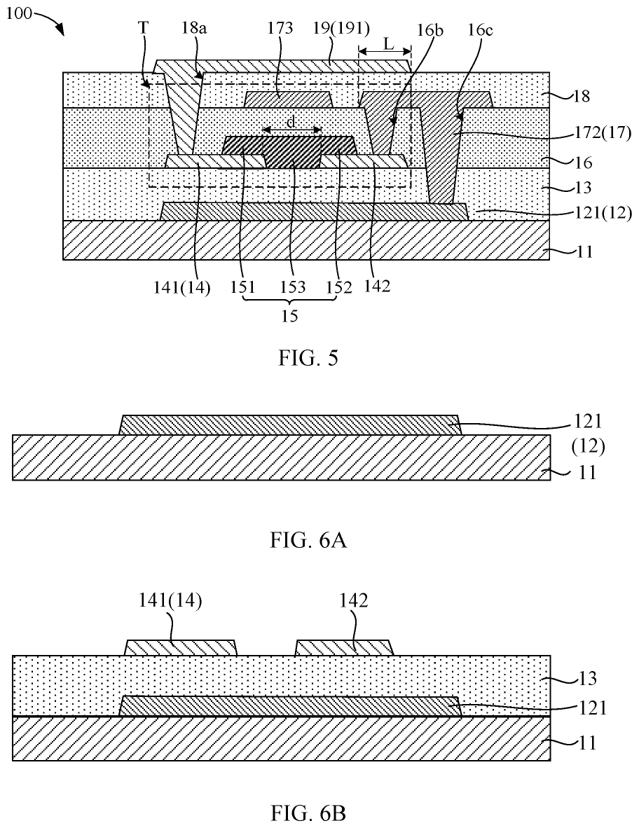

Referring to FIG. 5, FIG. 5 is a fifth schematic structural diagram of the driving backplane provided by the present application. A difference from the driving backplane 100 shown in FIG. 1 is that, in the embodiments of the present application, the connecting electrode 191 is directly connected to the sub-source electrode 141 through the connecting hole 18a.

In detail, the connecting hole 18a penetrates through the passivation layer 18 and extends to the sub-source electrode 141. The side surface of the sub-source electrode 141 away from the substrate 11 is exposed from the connecting hole 18a. Thus, the connecting electrode 191 is directly connected to the sub-source electrode 141 through the connecting hole 18a, thereby improving the contact yield.

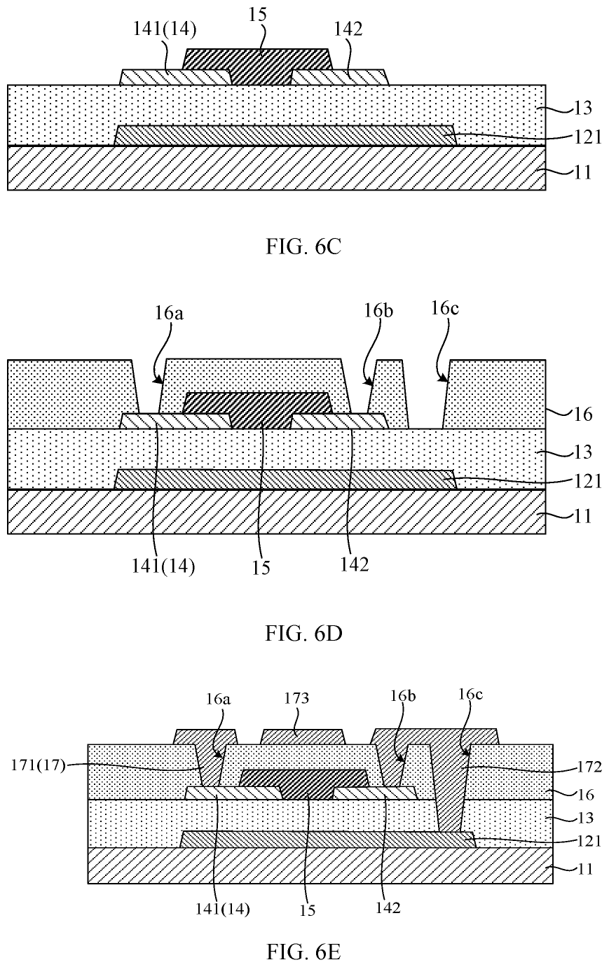

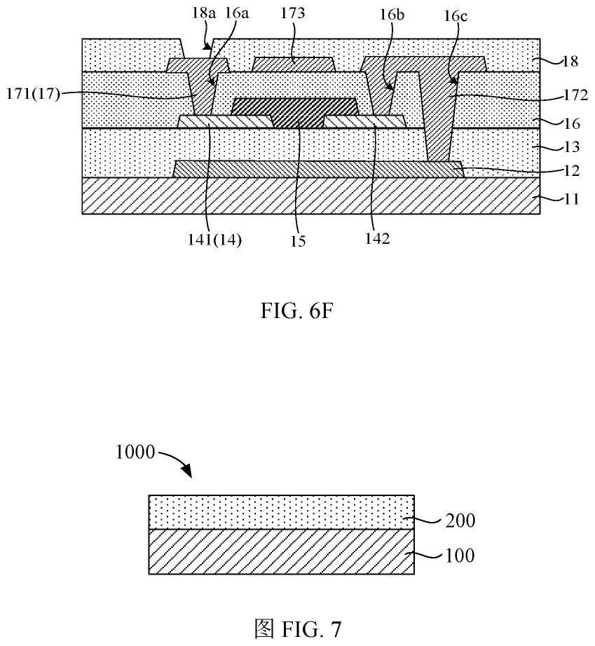

Please refer to FIG. 1 and FIG. 6A-FIG. 6F. FIG. 6A-FIG. 6F are schematic structural diagrams obtained in each step of a manufacturing method of the driving backplane provided by the present application. The embodiments of the present application are illustrated by taking the driving backplane 100 shown in FIG. 1 as an example, but cannot be understood as a limitation of the present application. The manufacturing method of the driving backplane 100 provided in the embodiments of the present application specifically includes the following steps:

Step 101: providing a substrate 11, and forming a light-shielding layer 12 on the substrate 11, as shown in FIG. 6A.

Among them, the substrate 11 can be double-layer Polyimide (PI) layer, or a glass substrate. The substrate 11 can also include a barrier layer, which can block water and oxygen.

In detail, a light-shielding material is coated on the substrate 11 by chemical vapor deposition, and then the light-shielding layer 12 is formed by patterning. The light-shielding layer 12 includes a light-shielding element 121.

Step 102: forming a buffer layer 13 on a side of the light-shielding layer 12 away from the substrate 11, and forming a first conductive layer 14 on a side of the buffer layer 13 away from the substrate 11, as shown in FIG. 6B.

The first conductive layer 14 includes a sub-source electrode 141 and a sub-drain electrode 142 arranged at intervals. A material of the first conductive layer 14 is mainly the metal oxide with small etching critical dimension change and low resistance value, such as ITO, IZO, ANCL, and other metals or metal oxide with low resistance value. A linewidth of the first conductive layer 14 is smaller, so that a distance between the sub-source electrode 141 and the sub-drain electrode 142 is more controllable, which is easier to narrow the channel.

Step 103: forming an active layer 15 on a side of the first conductive layer 14 away from the substrate 11 through a semiconductor coating process, as shown in FIG. 6C.

The active layer 15 includes a source contact portion 151, a drain contact portion 152, and a channel portion 153 connected to the source contact portion 151 and the drain contact portion 152. The source contact portion 151 covers part of the sub-source electrode 141. The drain contact portion 152 covers part of the sub-drain electrode 142. The channel portion 153 covers a gap between the sub-source electrode 141 and the sub-drain electrode 142. An orthographic projection of the light-shielding layer 12 on the substrate 11 covers at least an orthographic projection of the channel portion 153 on the substrate 11.

Step 104: forming an insulating layer 16 on a side of the active layer 15 away from the substrate 11, as shown in FIG. 6D.

In detail, the insulating layer 16 is patterned to form a first through hole 16a, a second through hole 16b, and a third through hole 16c. The first through hole 16a extends to the sub-source electrode 141, and a side surface of the sub-source electrode 141 away from the substrate 11 is exposed from the first through hole 16a. The second through hole 16b extends to the sub-drain electrode 142, and a side surface of the sub-drain electrode 142 away from the substrate 11 is exposed from the second through hole 16b. The third through hole 16c penetrates through the insulating layer 16, and extends to the light-shielding element 121. A side surface of the light-shielding element 121 away from the substrate 11 is exposed from the third through hole 16c.

Step 105: forming a second conductive layer 17 on a side of the insulating layer 16 away from the substrate 11, as shown in FIG. 6E.

The second conductive layer 17 includes a main source electrode 171, a main drain electrode 172, and a gate electrode 173. The gate electrode 173 is located between the main source electrode 171 and the main drain electrode 172. The orthographic projection of the gate electrode 173 on the substrate 11 covers at least the orthographic projection of the channel portion 153 on the substrate 11. The main source electrode 171 is connected to the sub-source electrode 141 through the first through hole 16a. The main drain electrode 172 is connected to the sub-drain electrode 142 through the second through hole 16b. The light-shielding element 121 is connected to the main drain electrode 172 through the third through hole 16c. Since the main drain electrode 172 is connected to the sub-drain electrode 142, the connection between the light-shielding element 121 and the sub-drain 142 electrode is realized.

Step 106: forming a passivation layer 18 on a side of the second conductive layer 17 away from the substrate 11.

As shown in FIG. 6F, the passivation layer 18 is provided with a connecting hole 18a. The surface of the main source electrode 171 away from the substrate 11 is exposed from the connecting hole 18a.

Step 107: forming a third conductive layer 19 on a side of the passivation layer 18 away from substrate 11, as shown in FIG. 1.

The third conductive layer 19 includes a connecting electrode 191. The connecting electrode 191 is connected to the main source electrode 171 through the connecting hole 18a. An orthographic projection of the connecting electrode 191 on the substrate 11 covers at least the orthographic projection of the active layer 15 on the substrate 11.

For example, the orthographic projection of the connecting electrode 191 on the substrate 11 can completely cover the orthographic projection of the active layer 15 on the substrate 11, and cover at least part of the orthographic projection of the main drain electrode 172 on the substrate 11. Along the direction perpendicular to the substrate 11, the length L of an overlap portion of the connecting electrode 191 and the main drain electrode 172 rangers from 2 micrometers to 5 micrometers. In this way, the shielding area of the active layer 15 is further increased to prevent water and oxygen erosion.

In detail, the length L of the overlap portion of the connecting electrode 191 and the main drain electrode 172 can be 2 microns, 3 microns, 4 microns, 5 microns, etc.

It should be noted that the materials and other characteristics of each functional film layer in the driving backplane 100 can refer to the above embodiments, and will not be repeated here.

For accordingly, please refer to FIG. 7. FIG. 7 is a schematic structural diagram of a display panel provided by the present application. The display panel 1000 includes a driving backplane 100 and light-emitting units 200 disposed on the driving backplane 100. The driving backplane 100 is the driving backplane 100 described in any one of the embodiments above. For details, please refer to the above content, which will not be repeated here.

In the present application, the display panel 1000 may be a OLED display panel or an MLED display panel, or a liquid crystal display panel. When the display panel 1000 is a OLED display panel, the light-emitting units 200 may include an organic light-emitting layer (not shown in the figure). When the display panel 1000 is an MLED display panel, the light-emitting units 200 may be Micro-LEDs or Mini-LEDs. When the display panel 1000 is an MLED display panel, the driving backplane 100 may be an array substrate of the display panel 1000.

The display panel 1000 provided by the embodiments of the present application includes the driving backplane 100. The driving backplane 100 is provided with the sub-source electrode and the sub-drain electrode. The active layer covers part of the sub-source electrode, part of the sub-drain electrode, and the gap between the sub-source electrode and sub-drain electrode, so that the channel portion is located between the sub-source electrode and the sub-drain electrode. The length of the channel portion can be adjusted by controlling the distance between the sub-source electrode and the sub-drain electrode, which is easier to achieve narrow channel than conducting through plasma in related technologies. Since the mobility increases with the decrease of the length of the channel portion, the mobility of the thin-film transistor can be improved and the reliability of the driving backplane can be improved.

The driving backplane and the display panel provided by present application have been introduced in detail above, and the description of the embodiments is merely intended to help understand the method and core ideas of the present application. At the same time, for those skilled in the art, based on the idea of the present application, there will be changes in the specific implementation and application scope. From the above discussion, the contents of this manual should not be understood as limitations on present application.

What is claimed is:

1. A driving backplane, comprising:
a substrate;
a first conductive layer, disposed on the substrate, comprising a sub-source electrode and a sub-drain electrode;
an active layer, disposed on a side of the first conductive layer away from the substrate, comprising a source contact portion, a drain contact portion, and a channel portion connected to the source contact portion and the drain contact portion, wherein the source contact portion covers part of the sub-source electrode, the drain contact portion covers part of the sub-drain electrode, and the channel portion covers a gap between the sub-source electrode and the sub-drain electrode;
an insulating layer, disposed on a side of the first conductive layer away from the substrate, covering the first conductive layer and the active layer; and
a second conductive layer, disposed on a side of the insulating layer away from the substrate, comprising a gate electrode and a main drain electrode connected to the sub-drain electrode, wherein an orthographic projection of the gate electrode on the substrate at least overlaps an orthographic projection of the channel portion on the substrate.

2. The driving backplane according to claim 1, wherein a material of the first conductive layer is different from a material of the second conductive layer, and a linewidth of the first conductive layer is less than a linewidth of the second conductive layer.

3. The driving backplane according to claim 1, wherein the orthographic projection of the gate electrode on the substrate overlaps at least part of an orthographic projection of the sub-source electrode on the substrate, and the orthographic projection of the gate electrode on the substrate overlaps at least part of an orthographic projection of the sub-drain electrode on the substrate.

4. The driving backplane according to claim 1, wherein the orthographic projection of the gate electrode on the substrate overlaps the orthographic projection of the channel portion on the substrate; the source contact portion comprises a first doped region, and the drain contact portion comprises a second doped region.

5. The driving backplane according to claim 1, further comprising:
a third conductive layer, located on a side of the second conductive layer away from the substrate, comprising a connecting electrode connected to the sub-source electrode, and an orthographic projection of the connecting electrode on the substrate overlapping an orthographic projection of the active layer on the substrate.

6. The driving backplane according to claim 5, wherein the second conductive layer further comprises a main source electrode connected to the sub-source electrode and the connecting electrode, and wherein the gate electrode is located between the main source electrode and the main drain electrode.

7. The driving backplane according to claim 5, wherein the orthographic projection of the connecting electrode on the substrate completely overlaps the orthographic projection of the active layer on the substrate, and overlaps at least part of an orthographic projection of the main drain electrode on the substrate; in a direction perpendicular to the substrate, a length of an overlapping part of the connecting electrode and the main drain electrode ranges from 2 microns to 5 microns.

8. The driving backplane according to claim 1, further comprising a third conductive layer located on a side of the second conductive layer away from the substrate, comprising a protective electrode and a connecting electrode connected to the sub-source electrode,
wherein an orthographic projection of the protective electrode on the substrate at least overlaps an orthographic projection of the active layer on the substrate.

9. The driving backplane according to claim 5, wherein the third conductive layer comprises a conductive metal layer and an anti-reflection layer disposed on a side of the conductive metal layer away from the substrate.

10. The driving backplane according to claim 9, wherein a material of the anti-reflection layer is indium zinc oxide, molybdenum oxide, or molybdenum nitride; the conductive metal layer is a composite metal layer made of copper and molybdenum.

11. The driving backplane according to claim 1, further comprising:
a light-shielding layer, disposed on a side of the first conductive layer near the substrate, comprising a light-shielding element, wherein an orthographic projection of the light-shielding element on the substrate overlaps an orthographic projection of the active layer on the substrate;
the insulating layer is provided with a third through hole penetrating through the insulating layer and extending to the light-shielding element; a side surface of the light-shielding element away from the substrate is exposed from the third through hole, and the light-shielding element is connected to the main drain through the third through hole.

12. The driving backplane according to claim 1, further comprising:
a light-shielding layer, disposed on a side of the first conductive layer near the substrate, comprising a light-shielding element; and
a buffer layer, disposed between the first conductive layer and the light-shielding layer and provided with a contact hole extending to the light-shielding element;
wherein an orthographic projection of the light-shielding element on the substrate overlaps an orthographic projection of the active layer on the substrate; a side surface of the light-shielding element away from the substrate is exposed from the contact hole, and the light-shielding element is connected to the sub-drain through the contact hole.

13. The driving backplane according to claim 1, wherein a thickness of the active layer ranges from 300 angstroms to 500 angstroms, and a length of the channel portion ranges from 3 microns to 5 microns.

14. The driving backplane according to claim 1, wherein a resistance value of the first conductive layer is greater than a resistance value of the second conductive layer.

15. A display panel, comprising a driving backplane and light-emitting units disposed on the driving backplane, wherein the driving backplane comprises:
a substrate;
a first conductive layer, disposed on the substrate, comprising a sub-source electrode and a sub-drain electrode;
an active layer, disposed on a side of the first conductive layer away from the substrate, comprising a source contact portion, a drain contact portion, and a channel portion connected to the source contact portion and the drain contact portion, wherein the source contact portion covers part of the sub-source electrode, the drain contact portion covers part of the sub-drain electrode, and the channel portion covers a gap between the sub-source electrode and the sub-drain electrode;
an insulating layer, disposed on a side of the first conductive layer away from the substrate, covering the first conductive layer and the active layer; and
a second conductive layer, disposed on a side of the insulating layer away from the substrate, comprising a gate electrode and a main drain electrode connected to the sub-drain electrode, wherein an orthographic projection of the gate electrode on the substrate at least overlaps an orthographic projection of the channel portion on the substrate.

16. The display panel according to claim 15, wherein a material of the first conductive layer is different from a material of the second conductive layer, and a linewidth of the first conductive layer is less than a linewidth of the second conductive layer.

17. The display panel according to claim 15, wherein the orthographic projection of the gate electrode on the substrate overlaps at least part of an orthographic projection of the sub-source electrode on the substrate, and the orthographic projection of the gate electrode on the substrate overlaps at least part of an orthographic projection of the sub-drain electrode on the substrate.

18. The display panel according to claim 15, wherein the orthographic projection of the gate electrode on the substrate overlaps the orthographic projection of the channel portion on the substrate; the source contact portion comprises a first doped region, and the drain contact portion comprises a second doped region.

19. The display panel according to claim 15, wherein the driving backplane further comprises a third conductive layer, the third conductive layer is located on a side of the second conductive layer away from the substrate, the third conductive layer comprises a connecting electrode, the connecting electrode is connected to the sub-source electrode, and an orthographic projection of the connecting electrode on the substrate overlapping an orthographic projection of the active layer on the substrate.

20. The display panel according to claim 19, wherein the second conductive layer further comprises a main source electrode connected to the sub-source electrode and the connecting electrode, and wherein the gate electrode is located between the main source electrode and the main drain electrode.
